(19) United States
(12) Patent Application Publication
(10) Pub. No.: US 2013/0169340 A1
(43) Pub. Date: Jul. 4, 2013

(54) CAPACITIVE TOUCH SENSOR INTERFACE

(71) Applicants: Yonghong Tao, Singapore (SG); Daniel J. Cooley, Forney, TX (US); Jeffrey L. Sonntag, Austin, TX (US); Hong Lee Koo, Singapore (SG)

(72) Inventors: Yonghong Tao, Singapore (SG); Daniel J. Cooley, Forney, TX (US); Jeffrey L. Sonntag, Austin, TX (US); Hong Lee Koo, Singapore (SG)

(21) Appl. No.: 13/340,772

(22) Filed: Dec. 30, 2011

(51) Int. Cl. G06G 7/18; G01R 27/26

(52) U.S. Cl. 327/336; 324/686

(57) ABSTRACT

A technique includes charging and discharging a capacitive sensor of a display. The technique includes regulating currents that are associated with the charging and discharging based at least in part on a reference time interval and determining a capacitance sensed by the capacitive sensor based at least in part on the regulating.

### BACKGROUND

A consumer electronic device, such as a smartphone or tablet computer, may contain a touchscreen that serves as both a visual display and a mechanism to receive user input. For user input purposes, the touchscreen allows the electronic device to sense both the presence of an object (a user's finger or a stylus, as examples) within the touchscreen's display area, as well as the specific location at which the display area is touched. The touchscreen may be constructed to sense user input in one of a number of different ways, such as through resistive sensing, capacitive sensing or surface acoustic waves.

One type of touchscreen technology senses self-capacitance. In this manner, the touchscreen may contain a conductive grid of rows and columns that may be formed on one or more conductive layers of the touchscreen. Each row and column is coupled to an associated electrode. Because the presence of a user's finger near a given row or column changes the capacitance of the associated electrode, the capacitances of the electrodes may be monitored for purposes of sensing user input.

### SUMMARY

In one exemplary embodiment, a technique includes charging and discharging a capacitor that is associated with a capacitive sensor of a display. The technique includes regulating currents that are associated with the charging and discharging based at least in part on a reference time interval and determining a capacitance of the capacitor based at least in part on the regulating.

In another exemplary embodiment, an apparatus includes a first integrator, a second integrator and a controller. The first integrator generates a first signal in response to a capacitor that is associated with a capacitive sensor of a display being charged. The second integrator generates a second signal in response to the capacitor being discharged. The controller is adapted to determine a capacitance of the capacitor based at least in part on the first and second signals.

In yet another exemplary embodiment, an apparatus includes an integrated circuit that includes a display; at least one integrator to charge and discharge a capacitor that is associated with a capacitive sensor of the display; a modulator and a controller. The modulator is adapted to regulate currents associated with the charging and discharging based at least in part on a reference time interval. The controller is adapted to determine a capacitance of the capacitor based at least in part on the currents.

Advantages and other desired features will become apparent from the following drawing, description and claims.

### BRIEF DESCRIPTION OF THE DRAWINGS

FIG. 1 is a block diagram of an electronic device according to an exemplary embodiment.

FIG. 2 is a schematic diagram of a positive integrator according to an exemplary embodiment.

FIGS. 3, 4, 5 and 6 are waveforms illustrating operation of the positive integrator of FIG. 2 according to an exemplary embodiment.

FIG. 7 is a schematic diagram of a negative integrator according to an exemplary embodiment.

FIGS. 8, 9, 10 and 11 are waveforms illustrating operation of the negative integrator of FIG. 2 according to an exemplary embodiment.

FIG. 12 is a schematic diagram of a reference clock generator according to an exemplary embodiment.

FIG. 13 is an illustration of a technique to determine a capacitance of a touchscreen electrode according to an exemplary embodiment.

FIG. 14 is a schematic diagram of a capacitive touch sensor interface according to an exemplary embodiment.

FIGS. 15A and 15B depict a flow diagram illustrating a technique to determine the capacitance of a touchscreen electrode according to an exemplary embodiment.

FIG. 16 is a schematic diagram of an integrator according to an exemplary embodiment.

FIG. 17 is an illustration of a configuration for the integrator of FIG. 16 to initialize the integrator for positive integration according to an exemplary embodiment.

FIG. 18 is an illustration of a configuration for the integrator of FIG. 16 to cause the integrator to perform positive integration according to an exemplary embodiment.

FIG. 19 an illustration of a configuration for the integrator of FIG. 16 to initialize the integrator for negative integration according to an exemplary embodiment.

FIG. 20 is an illustration of a configuration for the integrator of FIG. 16 to cause the integrator to perform negative integration according to an exemplary embodiment.

### DETAILED DESCRIPTION

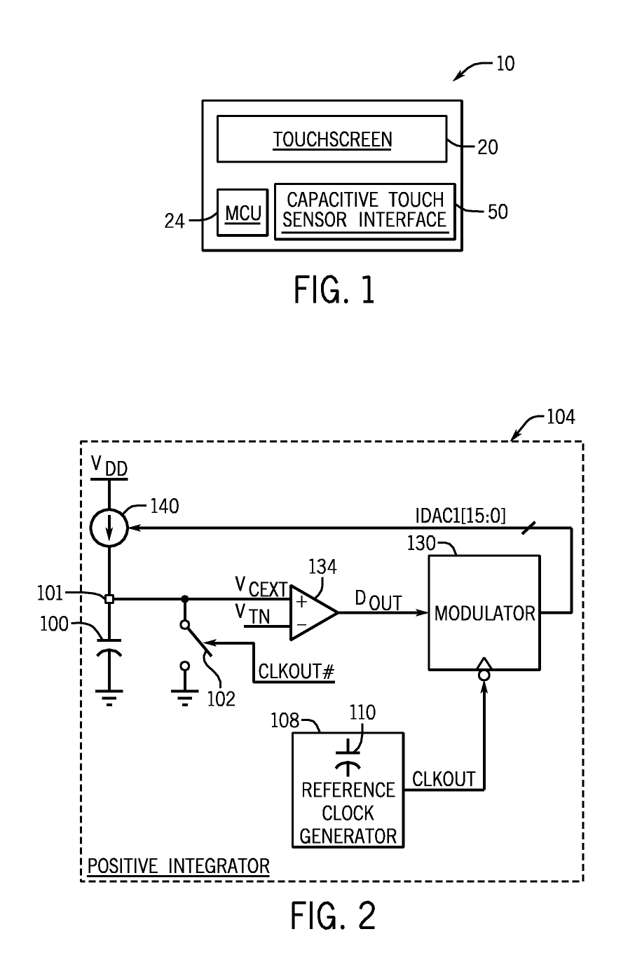

Referring to FIG. 1, in accordance with embodiments disclosed herein, an electronic device 10 may include a display, such as a touchscreen 20, for receiving user input and for displaying visual content (graphics, still images, video images, graphical user interfaces (GUIs), application-generated images, and so forth). As non-limiting examples, the electronic device 10 may be a smartphone, a cellular telephone, a portable digital assistant (PDA), a portable or notebook computer, a client computer, and so forth, depending on the particular embodiment. In accordance with exemplary embodiments, the touchscreen 20 includes electrodes that are electrically coupled to a capacitive touch sensor interface 50 of the electronic device 10. Depending on the particular implementation, the electrodes of the touchscreen 20 may be formed from one or multiple conductive layers (indium tin oxide (ITO) layers, for example) and may, in accordance with some implementations, be arranged in a grid of rows and columns, which spans across a display area of the touchscreen 20.

In general, the electrodes of the touchscreen 20 form capacitive sensors. In this manner, the capacitance (a self-capacitance, for example) of a given electrode of the touchscreen 20 changes in response to an object (a user's finger, for example) touching the touchscreen 20 near the electrode. The capacitive touch sensor interface 50 determines and monitors the capacitances of the electrodes for purposes of detecting the presence of an object in the touchscreen's display area and determining the location (rectangular coordinates, for example) of the object. Depending on the on particular embodiment, in response to sensing the presence of an object in the display area, the capacitive touch sensor interface 50 may alert a processor of the electronic device 10, such as a microcontroller unit (MCU 24), for example, (assert an interrupt request line, as a non-limiting example) so that a data transfer may be initiated to communicate data from the interface 50 indicative of the position of the object for further processing.

The capacitive touch sensor interface 50 may determine the capacitance of a given electrode using positive and/or negative integration of the associated capacitor current. For example, referring to FIG. 2, the capacitive touch sensor interface 50 may measure a positive integration rate of a current associated capacitor (represented by the capacitance of a capacitor 100 coupled to a given electrode 101) and determine the capacitance of the capacitor 100 based at least in part on this measurement. More specifically, the capacitive touch screen interface 50 may include a positive integrator 104, which includes a programmable current source 140 that is coupled to the electrode 101. The current source 140 provides a current to the electrode 101 to charge the capacitor 100 based on a digital value that is indicated by a multiple bit signal (called “IDAC1[15:0]” in FIG. 2). Charging the capacitor 100 causes a voltage (called “V_{CEXT}” in FIG. 2) of the capacitor 100 to rise in the form of a positive ramp (see exemplary ramp waveforms 150 and 152 of FIG. 5). The positive integrator 104 adjusts the current of the current source 104 (i.e., adjusts the IDAC1[15:0] signal) until the time rate at which the V_{CEXT} voltage is near or equal to a reference time rate. The value of the IDAC1[15:0] signal for this condition, in turn, indicates the capacitance of the capacitor 100.

More specifically, in accordance with some embodiments, the positive integrator 104 includes a reference clock generator 108 that generates a reference clock signal (called “CLKOUT” in FIG. 2) for purposes of providing a reference time interval to which a comparison may be made to determine the relative time rate at which the V_{CEXT} voltage rises. In accordance with some embodiments, the positive integrator 104 regulates the current of the current source 140 (via the IDAC1[15:0] signal) for purposes of causing the V_{CEXT} voltage to ramp from zero volts to a threshold voltage (called “V_{TN} in FIG. 2) during a given reference time segment of the CLKOUT clock signal.

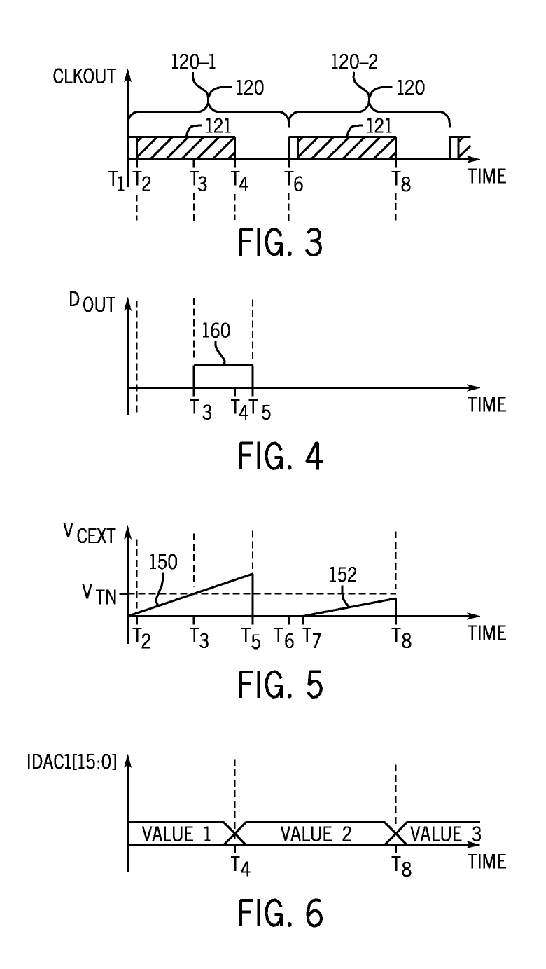

Referring to FIG. 3 in conjunction with FIG. 2, this regulation may occur over one or more cycles 120 (exemplary cycles 120-1 and 120-2 being depicted in FIG. 3) of the CLKOUT clock signal. For this example, the positive integrator 104 regulates the IDAC1[15:0] signal for purposes of causing the V_{CEXT} voltage to ramp from zero volts to the V_{TN} threshold voltage in a given reference time interval 121 of a given clock cycle 120. Referring also to FIGS. 4 and 5, the positive integrator 104 generates a signal called “D_{OUT}” which indicates a time rate of the V_{CEXT} voltage.

In this manner, for a given clock cycle 120, the positive integrator 104 asserts (drives to a logic one level, for example) the D_{OUT} signal for a duration that indicates the lead time of the V_{CEXT} voltage relative to the end of the time interval 121, i.e., how early (if at all) the V_{CEXT} voltage reaches the V_{TN} threshold relative to the end of the time interval 121. For the exemplary V_{CEXT} voltage that is depicted in FIG. 5, during the clock cycle 120-1, the V_{CEXT} voltage has a ramping waveform 150, i.e., the V_{CEXT} voltage ramps upwardly beginning at time T₂ (the beginning of the time interval 121). Because the V_{CEXT} voltage reaches the V_{TN} threshold at time T₃ (before the end of the time interval 121), the positive integrator 104 asserts (drives to a logic one value for this example) the D_{OUT} signal at time T₃ and keeps the D_{OUT} signal asserted until time T₄ (in response to the falling edge of the CLKOUT clock signal) to form a pulse 160 whose width indicates the relative lead time.

Because the V_{CEXT} voltage reaches the V threshold early in the clock cycle 120-1, the positive integrator 104 in a control iteration, adjusts the IDAC1[15:0] signal to correspondingly decrease the current that is provided by the current source 140 to decrease the slope of the V_{CEXT} voltage. In this manner, at time T₄, the positive integrator 104 changes the IDAC1[15:0] from a first value (see FIG. 6) to a second value to decrease the current that is supplied to the capacitor 100. Due to this change, for the subsequent clock cycle 120-2, V_{CEXT} voltage has a relatively smaller slope ramping waveform 152, which does not reach the V_{TN} threshold at the end of the time interval 121 for the clock cycle 120-2; and as a result, the positive integrator 104 does not assert the D_{OUT} signal during the clock cycle 120-2. Therefore, for the next clock cycle in this example, the positive integrator 104 increases the current from the current source 140. In this manner, the positive integrator 104 adjusts the IDAC1[15:0] signal to another value (at time T₈). As a more specific example, the positive integrator 104 may adjust the current provided by the current source 140 to a magnitude between the magnitudes used for the clock cycles 120-1 and 120-2.

By adjusting the current provided by the current source 140 over one or more clock cycles 120, eventually, the positive integrator 104 converges on a value for the IDAC1[15:0] signal that causes the V_{CEXT} voltage to reach the V_{TN} threshold voltage near or at the end of the time interval 121. This value, in turn, indicates a capacitance of the capacitor 100.

Referring to FIG. 2, in accordance with some embodiments, the positive integrator 104 includes a comparator 134 that provides the D_{OUT} signal. The non-inverting input terminal of the comparator 134 is coupled to the electrode 101, and the inverting input terminal of the comparator 134 receives the V_{TN} threshold voltage. A switch 102 of the positive integrator 104 is coupled between the electrode 101 and ground for purposes of discharging the capacitor 100 to initialize the positive integrator 104 for the next clock cycle 120. In this manner, in accordance with some embodiments, the switch 102 is controlled by the inverted CLKOUT signal (called the “CLKOUT#” signal in FIG. 2).

For example, in the clock cycle 120-1 in response to the falling edge of the CLKOUT signal (or rising edge of the CLKOUT#) at time T₄, the switch 102 closes to discharge the capacitor 100; and in response to the rising edge of the CLKOUT signal at time T₆, the switch 102 opens to allow the V_{CEXT} voltage to rise during the clock cycle 120-2. It is noted that, as depicted in FIG. 5, the V_{CEXT} voltage does not begin to rise until time T₇ (see FIG. 5) for this example due to the response time of the switch 102.

Among its other features, the positive integrator 104 also includes a modulator 130 that is clocked by the CLKOUT signal and generates the IDAC1[15:0] signal in response to the DOUT signal. In this manner, in accordance with some embodiments, the modulator 130 refines the IDAC1[15:0] signal (once per cycle of the CLKOUT signal) for purposes of converging on a value for the IDAC1[15:0] signal that causes the V_{CEXT} voltage to rise at or near the V_{TN} threshold voltage at the end of the time interval 121. Depending on the particular embodiment, the modulator 130 may be a successive approximation register (SAR) engine or a delta modulator, as non-limiting examples.

In accordance with some embodiments, the clock generator 108 sets the duration of the time interval 121 equal to a time for a voltage of a reference capacitor 110 to reach the V_{TN} threshold voltage when charged with a reference current. For these embodiments, after the modulator 130 converges on the value for IDAC1[15:0], the capacitance (called “Cₑₓₜ”) of the capacitor 100 may be determined as follows:

$${C}_{ext} = {C}_{ref} \cdot \frac{{I}_{A}}{{I}_{B}} , \qquad Eq . 1$$

where “C_{ref}” represents the capacitance of the reference capacitor 110; “I_{A}” represents the magnitude of the current of the current source 140 (as indicated by the IDAC1[15:0] signal); and “I_{B}” represents the magnitude of the reference current that is applied by the clock generator 108 to the reference capacitor 110.

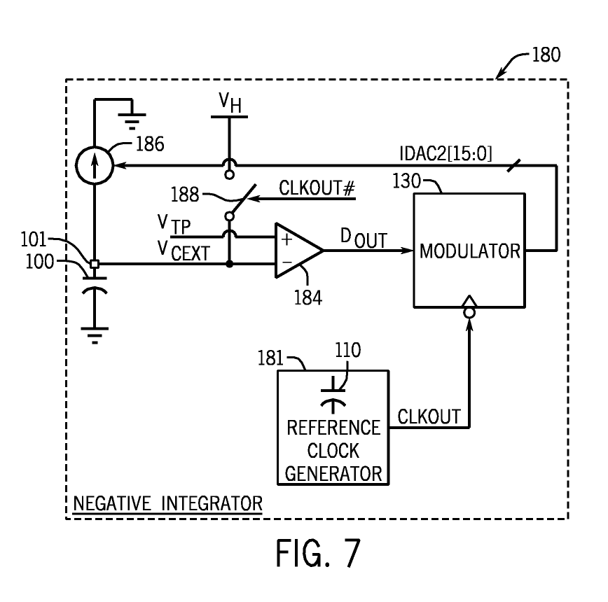

Referring to FIG. 7, in accordance with some embodiments, the capacitive touch sensor interface 50 also bases the determination of the capacitance of the capacitor 100 on a measured negative integration rate. More specifically, in accordance with embodiments disclosed herein, the capacitive touch screen interface 50 includes a negative integrator 180 that includes a programmable current source 186 that is coupled to the electrode 101. The current source 186 sinks a current from the electrode 101 to discharge the capacitor 100 based on a digital value that is indicated by a multiple bit signal (called “IDAC2[15:0]” in FIG. 7). Discharging the capacitor 100 causes the V_{CEXT} voltage of the capacitor 100 to decrease in the form of a negative ramp (see exemplary negative ramp waveforms 200 and 202 of FIG. 10). The negative integrator 180 adjusts the current of the current source 186 (i.e., adjusts the IDAC2[15:0] signal) until the time rate at which the V_{CEXT} voltage is near or equal to a reference time rate. The value of the IDAC2[15:0] signal for this condition, in turn, indicates the capacitance of the capacitor 100.

More specifically, the negative integrator 180 regulates the current of the current source 186 (via the IDAC2[15:0] signal) for purposes of causing the V_{CEXT} voltage to ramp downwardly from a predetermined voltage (called “V_{H}” in FIG. 7) to a threshold voltage (called “V_{TP} in FIG. 7) during a given time segment of the CLKOUT clock signal, which is provided by the reference clock generator 108.

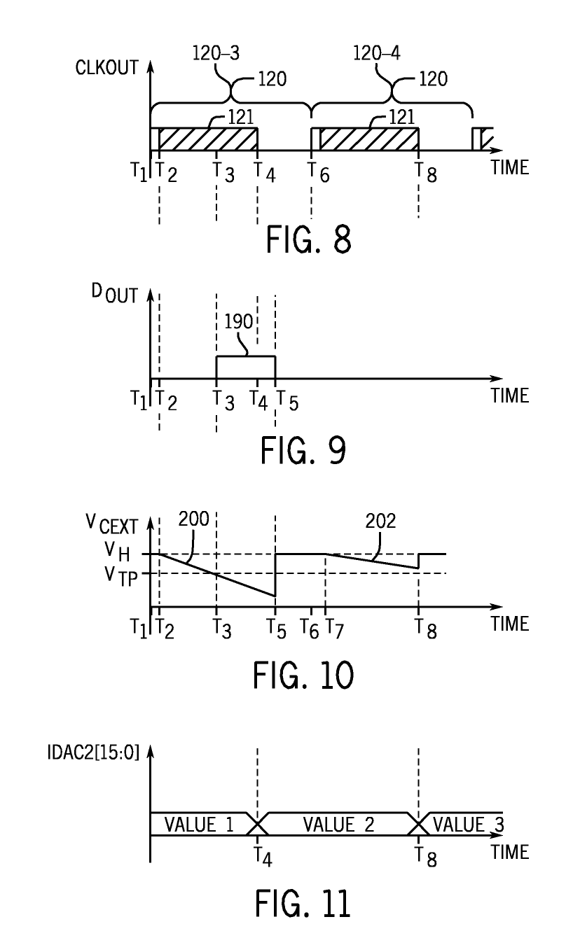

Referring to FIG. 8 in conjunction with FIG. 7, this regulation may occur over one or more cycles 120 (exemplary cycles 120-3 and 120-4 being depicted in FIG. 8) of a CLKOUT clock signal that is generated by a reference clock generator 181. For this example, the negative integrator 180 regulates the IDAC2[15:0] signal for purposes of causing the V_{CEXT} voltage to ramp downwardly from the V_{H} voltage to the V_{TP} threshold voltage in a given time segment 121 of a given clock cycle 120. Referring also to FIGS. 9 and 10, similar to the positive integrator 104, the negative integrator 180 generates a signal called “D_{OUT}” which indicates a time rate of the V_{CEXT} voltage.

In this manner, for a given clock cycle 120, the negative integrator 180 asserts (drives to a logic one level, for example) the D_{OUT} signal for a duration that indicates the lead time of the V_{CEXT} voltage relative to the end of the time interval 121, i.e., how early (if at all) the V_{CEXT} voltage reaches the V_{TP} threshold voltage relative to the end of the time interval 121. For the exemplary V_{CEXT} voltage that is depicted in FIG. 10, during the clock cycle 120-3, the V_{CEXT} voltage has a negative ramping waveform 200, i.e., the V_{CEXT} voltage ramps downwardly beginning at time T₂ (the beginning of the time segment 121). Because the V_{CEXT} voltage reaches the V_{TP} threshold voltage at time T₃ (before the end of the time segment 121), the negative integrator 180 asserts (drives to a logic one value for this example) the D_{OUT} signal at time T₃ and keeps the D_{OUT} signal asserted until time T₄ (in response to the falling edge of the CLKOUT clock signal) to form a pulse 190 whose width indicates the relative lead time.

Because the V_{CEXT} voltage reaches the V_{TP} threshold voltage early in the clock cycle 120-1, the negative integrator 180 adjusts the IDAC2[15:0] signal to correspondingly decrease the current that the current source 186 sinks to decrease the slope of the V_{CEXT} voltage. In this manner, at time T₄, the negative integrator 180 changes the IDAC2[15:0] from a first value (see FIG. 11) to a second value to decrease the current that is supplied to the capacitor 100. Due to this change, for the subsequent clock cycle 120-4, the V_{CEXT} voltage has a relatively smaller slope ramping waveform 202, which does not reach the V_{TP} threshold at the end of the time interval 121 for the clock cycle 120-4; and as a result, the negative integrator 180 does not assert the D_{OUT} signal during the clock cycle 120-4. Therefore, for the next clock cycle in this example, the negative integrator 180 increases the current that the current source 186 sinks. In this manner, the negative integrator 180 adjusts the IDAC2[15:0] signal to another value (at time T₈). As a more specific example, the negative integrator 180 may adjust the current that the current source 186 sinks to a magnitude between the magnitudes used for the clock cycles 120-3 and 120-4.

By adjusting the current that the current source 186 sinks over one or more clock cycles 120, eventually, the negative integrator 180 converges on a value for the IDAC2[15:0] signal that causes the V_{CEXT} voltage to reach the V_{TP} threshold voltage near the end of the time interval 121. This value, in turn, indicates the capacitance of the capacitor 100.

Referring to FIG. 7, in accordance with some embodiments, the negative integrator 180 includes a comparator 184 that provides the D_{OUT} signal. The inverting input terminal of the comparator 184 is coupled to the electrode 101, and the non-inverting input terminal of the comparator 184 receives the V_{TP} threshold voltage. A switch 188 of the negative integrator 180 is coupled between the electrode 101 and the V_{H} voltage for purposes of charging the capacitor 100 to the V_{H} voltage to initialize the negative integrator 180 for the next clock cycle 120. Similar to the positive integrator 104, the switch 188 may be controlled by CLKOUT# clock signal, which controls the switch 188 to charge the capacitor 100 between the time intervals 121.

Similar to the positive integrator 104, the negative integrator 180 includes a modulator 130, such as a SAR engine or a delta modulator (as non-limiting examples), which is clocked by the CLKOUT signal and generates the IDAC2[15:0] signal in response to the D_{OUT} signal. In this manner, in accordance with some embodiments, the modulator 185 refines the IDAC2[15:0] signal (once per cycle of the CLKOUT signal) for purposes of converging on a value for the IDAC2[15:0] signal that causes the V_{CEXT} voltage to decrease to or near the V_{TP} threshold voltage at the end of the time interval 121.

Assuming that the reference clock generator 181 uses the reference capacitor 110 and reference current as described above to set the duration of the time interval 121, a capacitance value for the capacitor 100 may be determined pursuant to Eq. 1 above, where “I_{A}” represents the magnitude of the current of the current source 186 (as indicated by the IDAC2[15:0] signal).

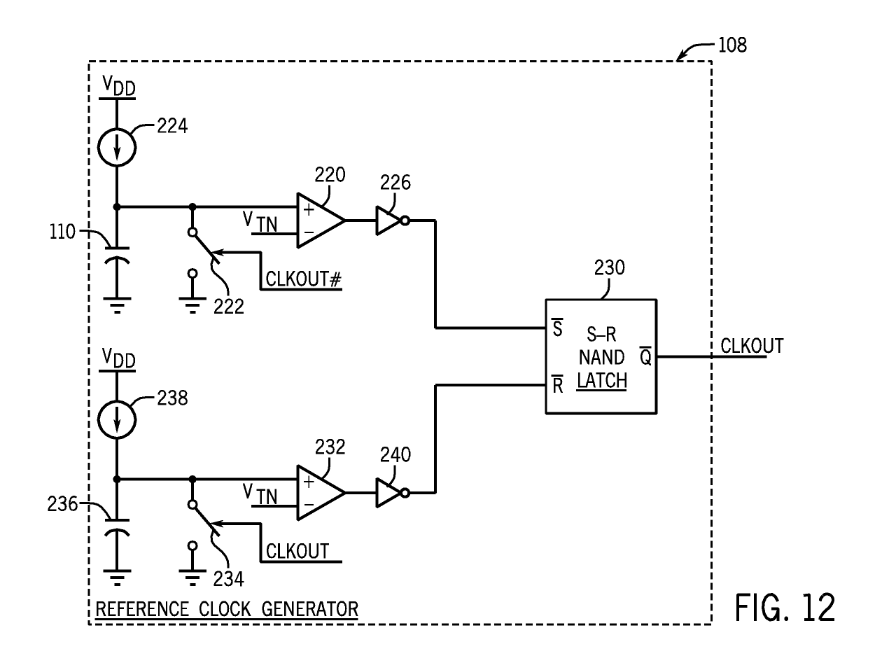

In accordance with some embodiments, the reference clock generator 110 may have an architecture similar to the one that is depicted in FIG. 12, although other architectures may be employed, in accordance with other embodiments of the invention. Referring to FIG. 12, for this example, the reference clock generator 110 include a set-reset (S-R) NAND latch 230 that provides the CLKOUT signal at its inverted output terminal. The inverted set input terminal of the latch 230 is coupled to the output terminal of an inverter 226, which, in turn, has an input terminal that is coupled to the output terminal of a comparator 220. The inverted reset input terminal of the latch 230 is coupled to the output terminal of an inverter 240, which, in turn, has an input terminal that is coupled to the output terminal of a comparator 232.

The comparator 220 and its associated circuitry control the time in which the CLKOUT clock signal is asserted (driven to a logic one level, for example) and control the duration of the time interval 221. The reference capacitor 110 is coupled between the non-inverting input terminal of the comparator 220 and ground, and a current source 224 is coupled between the V_{DD} supply voltage and the non-inverting input terminal of the comparator 220. A switch 222 is coupled between the non-inverting input terminal of the comparator 220 and ground and is controlled by the CLKOUT# clock signal. The inverting input terminal of the comparator 220 receives the V threshold voltage.

At the beginning of the time in which the CLKOUT clock signal is asserted, the comparator 220 de-asserts (drives to a logic zero level, for example) its output signal, which causes the inverted set input terminal of the latch 230 to be asserted (driven to a logic one level, for example). At this time, the inverted reset input terminal of the latch 230 is also asserted, which causes the CLKOUT clock signal to be asserted (remain at a logic one state, for example). While the CLKOUT clock signal is asserted, the current source 224 supplies a current to the capacitor 110, which causes the voltage of the capacitor 110 to rise. When the voltage of the capacitor 110 reaches the V_{TN} threshold voltage, the comparator 220 asserts (drives to a logic one level, for example) its output signal, which de-asserts (drives to a logic zero level, for example) the inverted set input signal to the latch 230 to cause the latch 230 to de-assert the CLKOUT signal.

The comparator 232 and its associated circuitry control the duration in which the CLKOUT clock signal is de-asserted (remains at the logic zero level, for example). The comparator 232 includes a capacitor 236 that is coupled between the non-inverting input terminal of the comparator 232 and ground, and a current source 238 is coupled between the V_{DD} supply voltage and the non-inverting input terminal of the comparator 232. A switch 234 is coupled between the non-inverting input terminal of the comparator 232 and ground and is controlled by the CLKOUT clock signal. The inverting input terminal of the comparator 232 receives the V_{TN} threshold voltage.

At the beginning of the time interval in which the CLKOUT signal is de-asserted, the comparator 232 de-asserts (drives to a logic zero level, for example) its output signal, which causes the inverted reset input terminal of the latch 230 to be asserted (driven to a logic one level, for example). At this time, the inverted set input terminal of the latch 230 is also asserted, which causes the CLKOUT clock signal to be asserted (remain at a logic one state, for example). While the CLKOUT clock signal is de-asserted, the current source 238 supplies a current to the capacitor 236, which causes the voltage of the capacitor 236 to rise. When the voltage of the capacitor 236 reaches the V_{TN} threshold voltage, the comparator 232 asserts (drives to a logic one level, for example) its output signal, which de-asserts (drives to a logic zero level, for example) the inverted reset input signal to the latch 230 to cause the latch 230 to assert the CLKOUT signal.

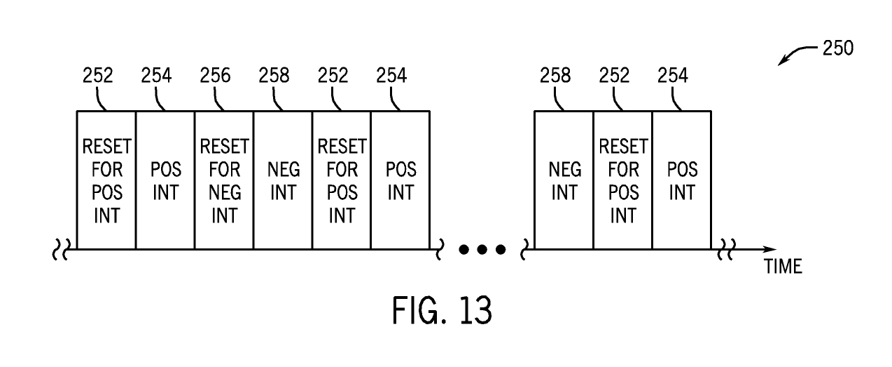

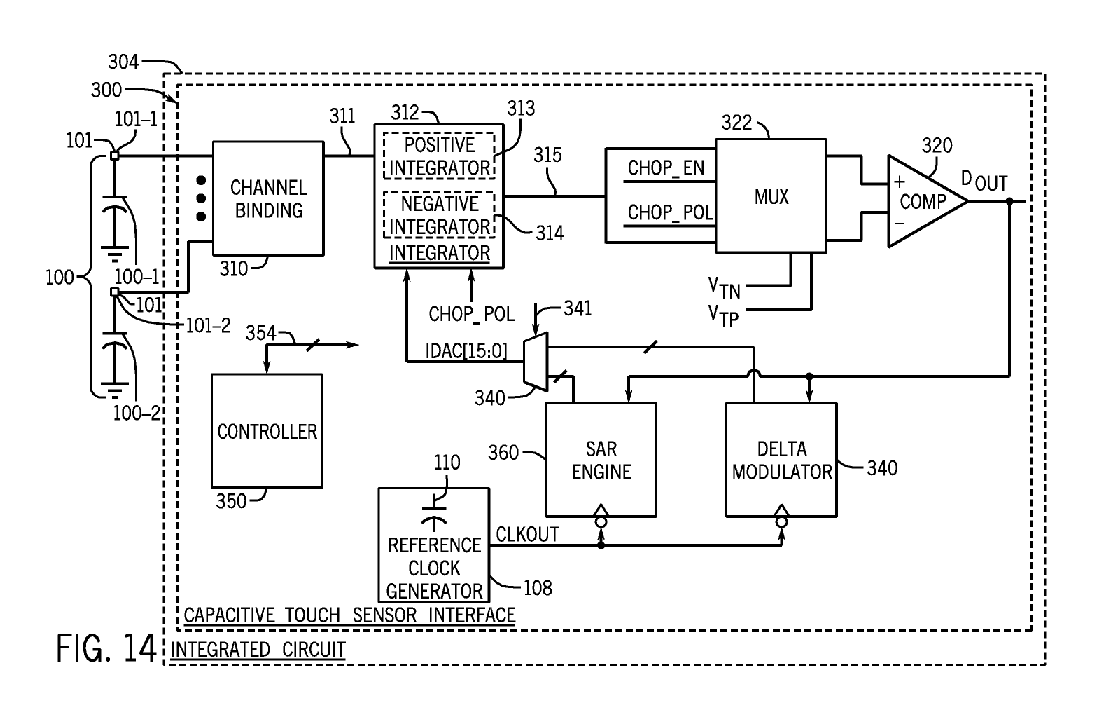

In accordance with embodiments disclosed herein, the capacitive touch sensor interface 50 uses time successive positive and negative integration of the capacitor 100 in a “chopping” technique for purposes of determining the capacitance of a given electrode 101. In this manner, referring to FIG. 13, in accordance with some embodiments of the invention, the capacitive touch sensor interface 50 uses a technique 250 that time multiplexes the charging and discharging of a given electrode's associated capacitor to derive two values: a first value for the capacitor's capacitance derived from positive integration and a second value for the capacitor's capacitance derived from negative integration. These two values may be combined (averaged, as a non-limiting example) for purposes of determining a final value for the capacitance. A particular advantage of such as technique is that the capacitive measurement may be relatively immune to noise, such as noise that may be present on the electrodes of the touchscreen 20 (see FIG. 1), for example, a relatively high level of noise when a two pin AC-to-DC charger is used to provide power to the electronic device 10.

In accordance with some embodiments, the technique 250 includes four repeating stages 252, 254, 256 and 258 that occur in different time multiplexed intervals: a stage 252 in which the capacitor 100 is reset, or discharged, for the next stage 254 in which positive integration occurs; and a stage 256 in which the capacitor 100 is reset, or charged, for the next stage 258 in which negative integration occurs. Thus, pursuant to the technique 250, the capacitor 100 is discharged such that the voltage of the capacitor 100 decreases to zero volts in the stage 252; the voltage of the capacitor 100 subsequently ramps upwardly in the stage 254 in an iteration to determine a capacitance value using position integration; the voltage of the capacitor 100 subsequently increases to the V_{H} voltage level in the stage 256; the voltage of the capacitor 100 subsequently ramps downwardly in the stage 258 in an iteration to determine a capacitance value using negative integration; the voltage of the capacitor 100 subsequently decreases to zero volts in another stage 252; and so forth. The number of iterations for determining the positive and negation integration-derived capacitance values may be predetermined; may be dynamically determined as the number for obtaining convergence for both positive and negative integration-derived values; or may be determined using other criteria, in accordance with other embodiments.

In accordance with some embodiments, the capacitive touch sensor interface 50 may have an architecture that is similar to the architecture of a capacitive touch sensor interface 300 that is depicted in FIG. 14. Referring to FIG. 14, in accordance with some embodiments, all of the components of the capacitive touch sensor interface 300 may be part of the same integrated circuit 304. For example, in accordance with some embodiments, all of the components of the capacitive touch sensor interface 300 may be fabricated on a single die or on multiple dies of a semiconductor package. In other embodiments, the components of the capacitive touch sensor interface 300 may be part of multiple integrated circuits. Thus, many variations are contemplated, which are within the scope of the appended claims.

The capacitive touch sensor interface 300 includes channel binding 310, or switches (such as complementary metal-oxide-semiconductor (CMOS) transmission gates, for example), which a controller 350 selectively opens and closes to couple a given electrode 101 (exemplary electrodes 101-1 and 101-2 being depicted in FIG. 14) to an input terminal 311 of an integrator 312 for purposes of determining the capacitance of an associated capacitor 100. As a non-limiting example, in accordance with some embodiments, the controller 350 may couple the electrodes 101 of the touchscreen 20 to the input terminal 311 in an ordered sequence such that when a given electrode 101 is coupled to the input terminal 311, the capacitive touch sensor interface 300 determines the capacitance associated with that electrode 101.

The integrator 312 includes a positive integrator 313 and a negative integrator 314 which may (as described below) or may not share components, depending on the particular embodiment. In accordance with some embodiments, the integrator 312 time multiplexes operations of the positive integrator 313 and the negative integrator 314 pursuant to the technique 250 (see FIG. 13) in response to a signal called “CHOP_POL” being asserted (driven to a logic one level, for example).

The integrator 312 may operate in a number of different modes of operation, depending on its specific configuration. For example, depending on the configuration, the integrator 312 may only use positive integration, may only use negative integration, may use a combination of positive and negative integration (such as the technique 250, for example), and so forth. The integrator 312 receives a signal called “IDAC[15:0],” which regulates a charging/discharging current of the capacitor 100 (depending on whether positive or negative integration is occurring) and converges on a value that indicates a capacitance of the capacitor 100.

The capacitive touch sensor interface 300 includes a comparator 320 that provides the D_{OUT} signal a multiplexing circuit 322 that controls the coupling of the appropriate signals to the input terminals of the comparator 320 based on whether the positive integrator 313 or the negative integrator 314 is active. When the positive integrator 313 is active (and the negative integrator 314 is not), the multiplexing circuitry 322 couples the non-inverting input terminal of the comparator 320 to an output terminal 315 of the integrator 312 and couples the inverting input terminal of the comparator 320 to the V_{TN} threshold voltage. When the negative integrator 314 is active (and the positive integrator 313 is not), the multiplexing circuitry 322 couples the inverting input terminal of the comparator 320 to the output terminal 315 and couples the non-inverting input terminal of the comparator 320 to the V_{TP} threshold voltage. In accordance with some embodiments, the multiplexing circuitry 322 is controlled by the CHOP_POL signal and a signal called “CHOP_EN,” which is asserted (driven to a logic one level, for example) to indicate whether chopping is enabled. When chopping is enabled, the CHOP_POL signal controls the connections to the comparator 320.

In accordance with some embodiments, the capacitive touch sensor interface 300 includes a SAR engine 360 and a delta modulator 340. Both the SAR engine 360 and the delta modulator 340 receive the D_{OUT} signal and are clocked by the inverted CLKOUT clock signal for this example. Selection of one of these components is controlled through a multiplexer 340 that receives a configuration signal at its select terminal 341. In this manner, the multiplexer 340 selects the output terminal of the SAR engine 360 or the output terminal of the delta modulator 340 to provide the IDAC[15:0] signal, depending on the configuration signal.

Depending on the particular embodiment, the controller 350 may or not be part of the integrated circuit 304. The controller 350, in general, has input and output terminals 354 to perform such functions as controlling the electrode selections of the channel binding 310; controlling operations of the positive 313 and negative 314 integrators; controlling time multiplexing of the positive 313 and negative 314 integrators; controlling operations of the multiplexers 322, 324 and 340; determining a capacitance value for a given electrode based on capacitance values obtained through positive and/or negative integration; determining a capacitance value for a given electrode based on capacitance values obtained through time multiplexed positive and negative integration; and so forth.

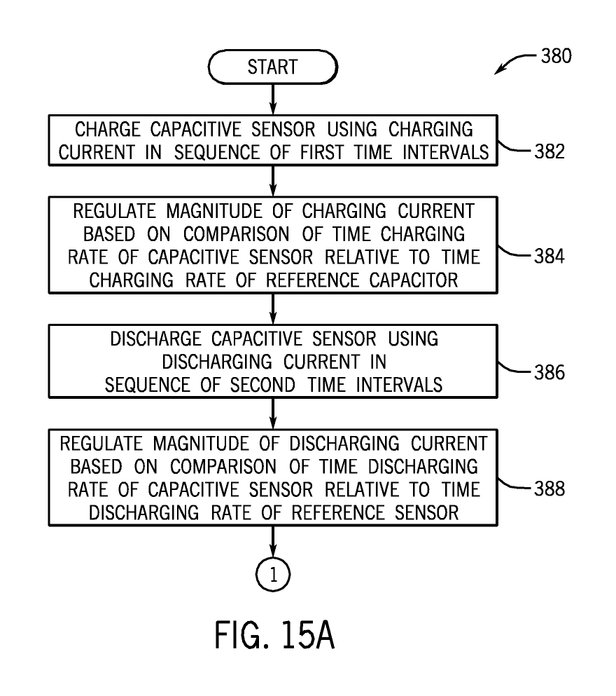

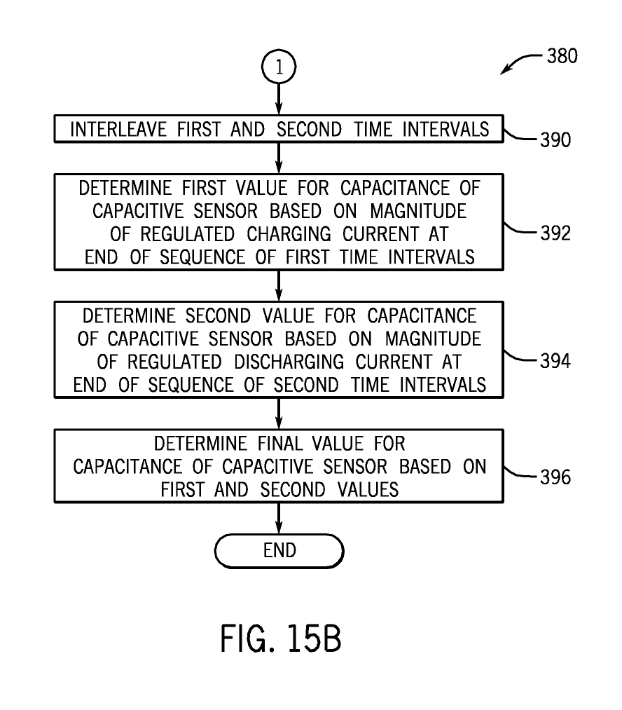

Thus, in accordance with some embodiments, the capacitive touch sensor interface 300 may be used to perform a technique 380 that is depicted in FIGS. 15A and 15B. Referring to FIG. 15A, the technique 380 includes charging (block 382) a capacitive sensor using a charging current in a sequence of first time intervals; and regulating (block 384) a magnitude of the charging current based on a comparison of a time charging rate of the capacitive sensor relative to a time charging rate of a reference capacitor. The technique 380 further includes discharging (block 386) the capacitive sensor using a discharging current in a sequence of second time intervals; and regulating (block 388) a magnitude of the discharging current based on a comparison of a time discharging rate of the capacitive sensor relative to a time discharging rate of the reference capacitor.

Referring to FIG. 15B, the first and second time intervals are time multiplexed, or interleaved, pursuant to block 390. The technique 380 includes determining (block 392) a first value for the capacitive sensor based on the magnitude of the regulated charging current at the end of the sequence of first time intervals and determining (block 394) a second value for the capacitive sensor based on the magnitude of the regulated discharging current at the end of the sequence of second time intervals. The technique 380 includes determining (block 396) a final value for the capacitance of the capacitive sensor based on the first and second values.

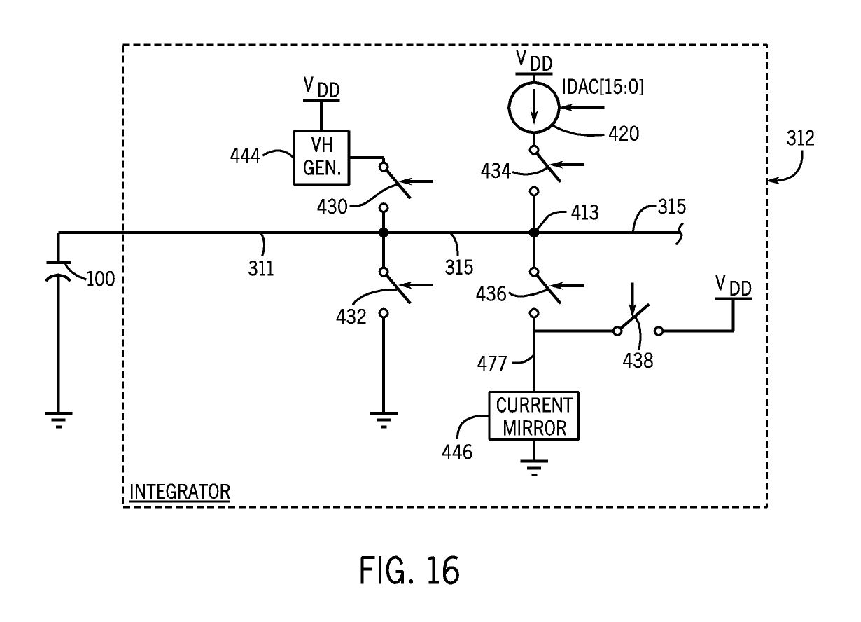

FIG. 16 depicts an exemplary architecture of the integrator 312, in accordance with some embodiments. It is noted that integrator 312 may have other architectures, in accordance with other embodiments. For the architecture that is depicted in FIG. 16, the integrator 312 has components that are used to perform both positive and negative integration. In general, integrator 312 has switches that are selectively opened and closed (via signals from the controller 350 (see FIG. 14), for example) for purposes of configuring the integrator 312 to operate in one of four states, which correspond to the stages 252, 254, 256 and 258 (see FIG. 13).

As depicted in FIG. 16, the input 311 and output 315 terminals of the integrator 312, for this example, are coupled together at a node 413. A switch 432 is coupled between the node 413 and ground. Another switch 430 is coupled between the node 413 and an output terminal of a V_{H} generator 444 that provides and regulates the V_{H} voltage in response to the V_{DD} supply voltage. For purposes of providing currents to both charge and discharge the capacitor 100, the integrator 312 includes a current source 420 (whose current is programmable via the IDAC[15:0] signal) and a current mirror 446. The current source 420 is selectively coupled to the node 413 via a switch 434. Although not depicted in FIG. 16, the current source 420 is coupled to the current mirror 446, including times when the switch 434 is open to isolate the current source 420 from the node 413.

The current minor 446 has a current path 447 that communicates a current that is a mirrored version of the current of the current source 420. As a non-limiting example, in accordance with some embodiments, the current minor 446 may include metal-oxide-semiconductor field-effect-transistors (MOSFETs) that share a common gate-to-source voltage and produce mirrored currents that are scaled according to the relative aspect ratios of the transistors. The current path 447 is selectively coupled to either the node 413 (via a switch 436) or the V_{DD} supply voltage (via a switch 438).

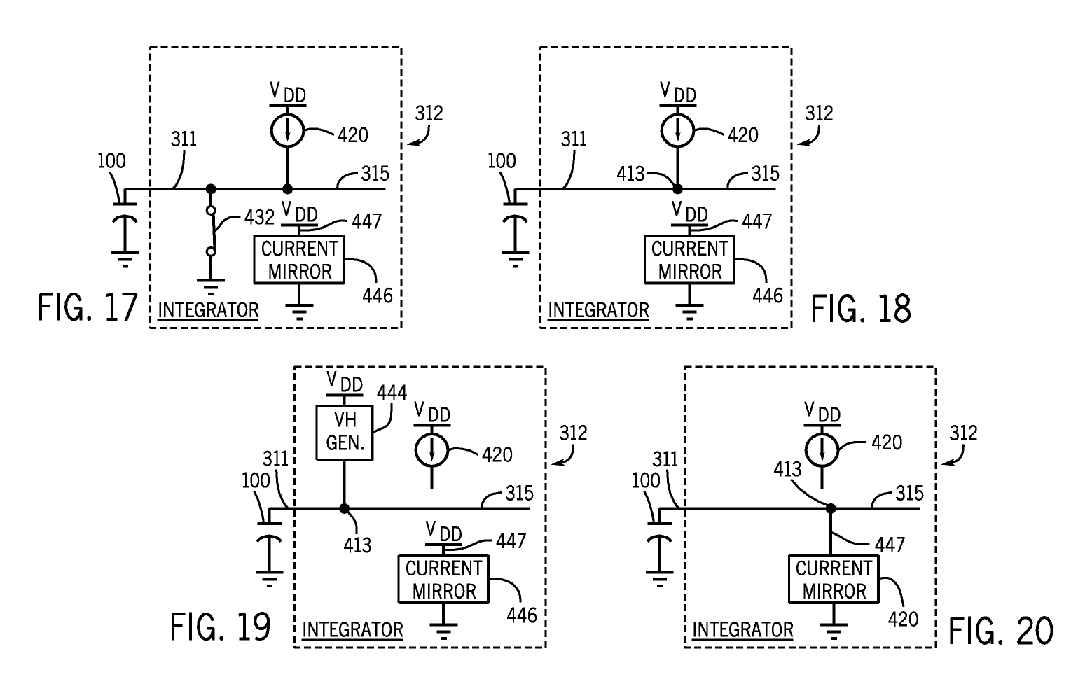

FIGS. 17, 18, 19 and 20 depict the integrator 312 during the stages 252 (FIG. 17), 254 (FIG. 18), 256 (FIGS. 19) and 258 (FIG. 20). Referring to FIG. 17 in conjunction with FIG. 16, during the stage 252, the integrator 312 resets the capacitor 100 to initialize the integrator 312 for the upcoming positive integration. In the manner, for the stage 252, the switch 432 is closed to discharge the capacitor 100; the switch 434 is closed to couple the current source 420 to the node 413; the switch 436 is open and the switch 438 is closed to couple the current path 447 of the current mirror 446 to the V_{DD} supply voltage; and the switch 430 is open to isolate the V_{H} generator 444 from the node 413.

Referring to FIG. 18 in conjunction with FIG. 16, during the stage 254, the integrator 312 charges the capacitor 100 to perform positive integration. In the manner, for the stage 254, the switch 432 is opened to allow the voltage of the capacitor 100 to rise; the switch 434 is closed to couple the current source 420 to the node 413 for purposes of supplying a charging current to the capacitor 100; the switch 436 is open and the switch 438 is closed to couple the current path 447 of the current minor 446 to the V_{DD} supply voltage; and the switch 430 is open to isolate the V_{H} generator 444 from the node 413.

Referring to FIG. 19 in conjunction with FIG. 16, during the stage 256, the integrator 312 resets the capacitor 100 in preparation for the upcoming negative integration. In the manner, for the stage 256, the switch 430 is closed to supply the V_{H} voltage to the node 413; the switch 434 is opened to isolate the current source 420 from the node 413; the switch 436 is open and the switch 438 is closed to couple the current path 447 of the current minor 446 to the V_{DD} supply voltage; and the switch 432 is opened.

Referring to FIG. 20 in conjunction with FIG. 16, during the stage 258, the integrator 312 discharges the capacitor 100 to perform negative integration. In the manner, for the stage 258, the switch 430 is opened to isolate the V_{H} voltage from the node 413; the switch 434 is opened to isolate the current source 420 from the node 413; the switch 436 is closed and the switch 438 is open to couple the current path 447 of the current minor 446 to the node 413 for purposes of sinking a current from the capacitor 100 to discharge the capacitor 100; and the switch 432 is opened.

While a limited number of embodiments have been disclosed herein, those skilled in the art, having the benefit of this disclosure, will appreciate numerous modifications and variations therefrom. It is intended that the appended claims cover all such modifications and variations.

What is claimed is:

1. A method comprising:
charging and discharging a capacitor associated with a capacitive sensor of a display;
regulating currents associated with the charging and discharging based at least in part on a reference time interval; and
determining a capacitance of the capacitor based at least in part on the regulating of the currents.

2. The method of claim 1, wherein the regulating of the currents comprises:
regulating a current used to discharge the capacitor to regulate a discharging time rate for the capacitor based at least in part on a time interval associated with a reference capacitor.

3. The method of claim 1, wherein the regulating of the currents comprises:
estimating a magnitude for a current to discharge the capacitor;
using the current having the estimated magnitude to discharge the capacitor;
comparing a time interval to discharge the capacitor sensor using the current having the estimated magnitude with the reference time interval; and
refining the estimate based on the comparison.

4. The method of claim 3, wherein the refining of the estimate comprises using a successive approximation register (SAR) engine to regulate the magnitude based at least in part on the comparison.

5. The method of claim 3, wherein the refining of the estimate comprises using a delta modulator to regulate the magnitude based at least in part on the comparison.

6. The method of claim 1, wherein
the charging and discharging comprises charging and discharging the capacitor in cycles, the cycle comprising a first portion in which the capacitor is charged and a second subsequent portion in which the capacitor is discharged.

7. The method of claim 1, wherein the determining comprises determining a first value for the capacitance sensed by the capacitive sensor based on the charging, determining a second value for the capacitance sensed by the capacitive sensor based on the discharging, and combining the first and second values to determine a third value for the capacitance sensed by the capacitive sensor.

8. An apparatus comprising:
a first integrator to generate a first signal in response to a capacitor associated with a capacitive sensor of a display being charged;
a second integrator to generate a second signal in response to the capacitor being discharged; and
a controller adapted to determine a capacitance sensed by the capacitor based at least in part on the first and second signals.

9. The apparatus of claim 8, further comprising a modulator adapted to regulate operations of the first and second integrators based at least in part on a time interval regulated using a reference capacitor.

10. The apparatus of claim 8, wherein the modulator is adapted to regulate a discharging time rate of the capacitor to regulate a predefined relationship between the discharging time rate of the capacitor and a reference discharging time rate.

11. The apparatus of claim 8, wherein the modulator is adapted to regulate a charging time rate of the capacitor to regulate a predefined relationship between the charging time rate of the capacitor and a reference charging time rate.

12. The apparatus of claim 9, wherein the modulator comprises a successive approximation register engine (SAR) or a delta modulator.

13. The apparatus of claim 9, wherein the modulator is adapted to estimate a magnitude for a current to discharge the capacitor and the second integrator is adapted to use the current having the estimated magnitude to discharge the capacitor, the apparatus further comprising:
a comparator to compare a time interval to discharge the capacitor sensor using the current having the estimated magnitude with a reference time interval.

14. The apparatus of claim 8, further comprising a modulator and a current source adapted to be regulated by the modulator to regulate operation of at least one of the first regulator and the second regulator.

15. The apparatus of claim 8, wherein the first and second integrators are adapted to operate in a time sequence to successively charge and discharge the capacitor.

16. The apparatus of claim 15, further comprising a modulator adapted to refine the estimate based on the comparison.

17. An apparatus comprising:
a display; and
an integrated circuit comprising at least one integrator to charge and discharge a capacitor associated with a capacitive sensor of the display, a modulator and a controller,
wherein the modulator is adapted to regulate currents associated with the charging and discharging based at least in part on a reference time interval, and the controller is adapted to determine a capacitance of the capacitor sensed by the capacitive sensor based at least in part on the currents.

18. The apparatus of claim 17, wherein the capacitor is charged and discharged in cycles, the cycle comprising a first portion in which the capacitor is charged and a second subsequent portion in which the capacitor sensor is discharged.

19. The apparatus of claim 17, wherein the at least one integrator comprises a first integrator and a second integrator, the integrated circuit further comprises a current source, and the modulator is adapted to regulate the current source to regulate the currents associated with the charging and discharging.

20. The apparatus of claim 17, wherein the controller is adapted to determine a first value for the capacitance sensed by the capacitive sensor based on the charging, determine a second value for the capacitance sensed by the capacitive sensor based on the discharging, and combine the first and second values to determine a third value for the capacitance sensed by the capacitive sensor.
